(19) United States
(12) Patent Application Publication
(10) Pub. No.: US 2026/0075715 A1
(43) Pub. Date: Mar. 12, 2026

(54) POWER MODULE AND AUXILIARY SUPPORTING DEVICE ADAPTED THERETO

(71) Applicant: Delta Electronics (Thailand) Public Company Limited, Samutprakarn (TH)

(72) Inventors: Hongming Li, Shanghai (CN); Kai Dong, Shanghai (CN); Xin Yang, Shanghai (CN); Xi Chen, Shanghai (CN)

(21) Appl. No.: 19/316,004

(22) Filed: Sep. 2, 2025

(30) Foreign Application Priority Data
Sep. 6, 2024 (CN) 202411257255.6

(51) Int. Cl. H05K 1/14; H05K 1/02

(52) U.S. Cl. CPC H05K 1/141; H05K 1/0203

(57) ABSTRACT

A power module and an auxiliary supporting device adapted thereto are provided. The auxiliary supporting device is used to maintain a first circuit board in a vertical state on a second circuit board. The auxiliary supporting device includes a first plate and a second plate. The first plate is parallel to and fixed to the first circuit board. The second plate is extended from the first plate in a direction away from the first circuit board. A bottom edge of the second plate is disposed on a surface of the second circuit board facing the first circuit board. The auxiliary supporting device is universally suitable for different combinations between the first plate and the second plate without the need of customized tool.

### CROSS-REFERENCE TO RELATED APPLICATIONS

This non-provisional application claims priority to China Patent Application No. 202411257255.6 filed on Sep. 6, 2024. The entire contents of application are incorporated herein by reference for all purposes.

### FIELD OF THE INVENTION

The present disclosure relates to the field of electronic technology, and more particularly to the power module.

### BACKGROUND OF THE INVENTION

As electronic devices become thinner and smaller, for power modules, the practice of vertically welding a side board to a main board in power modules has been widely adopted to meet the demand for improved efficiency and power density.

Generally, after inserting the side board on the main board, an additional customized tool is needed to maintain the side board in a vertical state during wave soldering, thereby avoiding wavering, tilting or even tipping.

However, due to the variety of main board and side board configurations, different customized tools must be designed, which significantly increases the cost and time.

Therefore, it would be desirable to provide an auxiliary supporting device that is adaptable for use across various combinations of main boards and side boards, and which can reliably maintain the side board in a vertical state on the main board during the soldering process, thereby ensuring high-quality soldering results.

### SUMMARY OF THE INVENTION

An object of the present disclosure is to provide a power module and an auxiliary supporting device adapted thereto for solving the drawbacks described above.

In accordance with an aspect of the present disclosure, an auxiliary supporting device is provided. The auxiliary supporting device is used to maintain a first circuit board in a vertical state on a second circuit board. The auxiliary supporting device includes a first plate and a second plate. The first plate is parallel to and fixed to the first circuit board. The second plate is extended from the first plate in a direction away from the first circuit board. A bottom edge of the second plate is disposed on a surface of the second circuit board facing the first circuit board.

In accordance with another aspect of the present disclosure, a power module is provided. The power module includes a first circuit board and a second circuit board. The first circuit board is disposed on the second circuit board in a vertical state through at least one of the auxiliary supporting device as described above.

The auxiliary supporting device of the present disclosure achieves the universal usage through the innovative structural design thereof. The auxiliary supporting device is capable of adapting to different combinations of the main boards and the side boards in the power module, thereby reliably maintaining the side board in a vertical orientation across different configurations. Moreover, the auxiliary supporting device is fixed to the side board through soldering, which can be achieved at the same with the original soldering process for the power module and is easy to conduct. In addition, the auxiliary supporting device of the present disclosure is also cost effective due to the simple structure and unlimited material thereof.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a schematic view showing a power module adopting an auxiliary supporting device according to an embodiment of the present disclosure;

FIG. 2A is a schematic view showing an auxiliary supporting device according to an embodiment of the present disclosure;

FIG. 2B is a schematic view showing the auxiliary supporting device according to the embodiment of the present disclosure from another view angle;

FIG. 2C is a schematic view showing an auxiliary supporting device according to another embodiment of the present disclosure;

FIG. 3A to FIG. 3B illustrate a first application of an auxiliary supporting device according to an embodiment of the present disclosure;

FIG. 4A to FIG. 4B illustrate a second application of an auxiliary supporting device according to an embodiment of the present disclosure;

FIG. 5A to FIG. 5B illustrate a third application of an auxiliary supporting device according to an embodiment of the present disclosure;

FIG. 6 is a schematic view showing an auxiliary supporting device according to another embodiment of the present disclosure;

FIG. 7 is a schematic view showing an auxiliary supporting device according to another embodiment of the present disclosure;

FIG. 8 is a schematic view showing an auxiliary supporting device according to another embodiment of the present disclosure;

FIG. 9A to FIG. 9D are schematic views showing exemplary pads disposed on a side board of the present disclosure; and

FIG. 10 is a schematic view showing engaging portions respectively of the auxiliary supporting device and the side board according to an embodiment of the present disclosure.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed.

Although terms “first” and “second” are used to describe different components/devices/circuits, the components/devices/circuits are not limited thereto, and the terms are only used for differentiation. For example, the first component can be referred as the second component, and similarly, the second component also can be referred as the first component, without departing from the scope of the embodiment. Further, in order to conveniently describe the relationship between a component or feature and another component(s) or feature(s) in the figures, spatially relative terms may be used, such as “under”, “below”, “lower”, “above”, “upper” and similar terms. In addition to the orientation depicted in the figures, the spatially relative terms are used to encompass different orientations of the device in use or operation. The device may be otherwise oriented (e.g., rotated 90 degrees or at other orientations) and the descriptions of the spatially relative terms used should be interpreted accordingly.

Followings are detailed descriptions of some embodiments of the present disclosure. The following embodiments and features thereof can be combined in the absence of conflict, and identical or similar concepts or procedures that might be applied in certain embodiments are omitted.

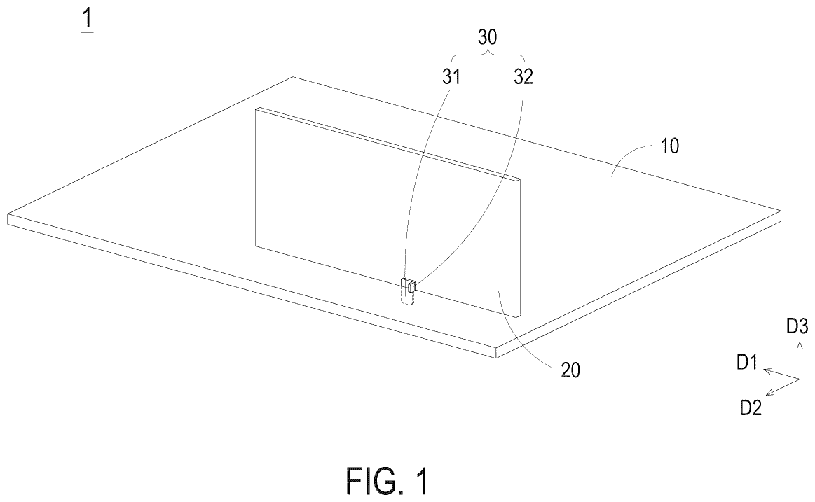

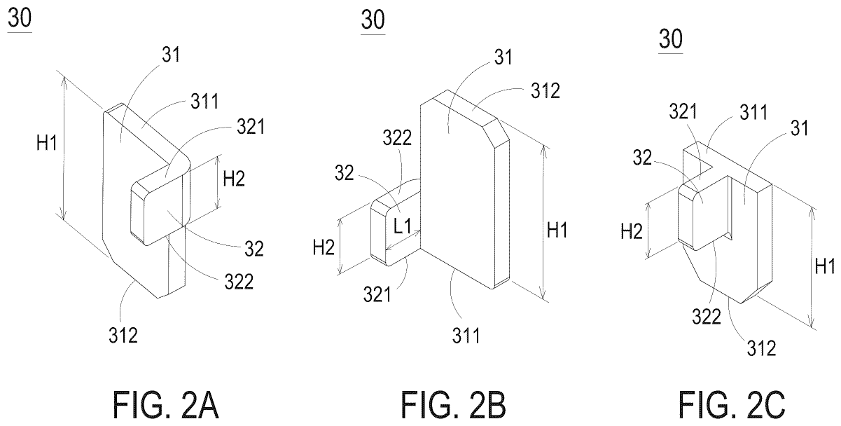

Please refer to FIG. 1, FIG. 2A and FIG. 2B. FIG. 1 is a schematic view showing a power module adopting an auxiliary supporting device according to an embodiment of the present disclosure, FIG. 2A is a schematic view showing an auxiliary supporting device according to an embodiment of the present disclosure, and FIG. 2B is a schematic view showing the auxiliary supporting device according to the embodiment of the present disclosure from another view angle. A power module 1 includes a first circuit board, a second circuit board and an auxiliary supporting device 30. As shown in FIG. 1, the first circuit board is used as a side board 20 vertically disposed on the second circuit board, which is used as a main board 10, and the auxiliary supporting device 30 is used to assist the side board 20 in maintaining in a vertical state. Notably, types and positions of electronic components on the main board 10 and the side board 20, position of the side board 20 related to the main board 10 and size of the side board 20 all can be different in accordance with the practical situations, and thus, the main board 10 and the side board 20 in FIG. 1 are illustrated as bare boards.

The auxiliary supporting device 30 includes a first plate 31 and a second plate 32. The first plate 31 is parallel to the side board 20, and the second plate 32 is extended from the first plate 31 in a direction away from the side board 20. In other words, the first plate 31 and the second plate 32 are two intersecting planes, wherein the first plate 31 is used to maintain the side board 20 in a vertical state, and the second plate 32 is used to stabilize the vertical state of the side board 20, such as for avoiding wavering, tilting or tipping. In an embodiment, the first plate 31 and the second plate 32 are integrally formed, but not limited thereto.

An intersecting angle and an intersecting position between a plane of the first plate 31 and a plane of the second plate 32 can be different. For example, the intersecting angle of two planes may be 90° (as shown in FIG. 2A and FIG. 2B), or may be other angles, e.g., an angle ranged between 45° and 135°, as long as the second plate 32 can provide sufficient support to ensure that the side board 20 remains in a vertical state, without being limited to figures. Moreover, an extension length of the second plate 32 from the first plate 31 is defined in accordance with a height of the side board. That is, the extension length of the second plate 32 related to the first plate 31 is positively related to the height of the side board 20 in a normal direction of the main board 10. When the height of the side board 20 in a D3 direction (the normal direction of the main board 10) is greater, a distance between the free end of the second plate 32 and the first plate 31 should accordingly be larger, so as to sufficiently support the side board 20 and avoid tilting or tipping. For example, as shown in FIG. 2B and FIG. 7, a second plate 32a of an auxiliary supporting device 30a in FIG. 7 has a greater extension length L2 related to a first plate 31a than an extension length L1 of the second plate 32 related to the first plate 31 in FIG. 2B, so that, compared with the auxiliary supporting device 30, the auxiliary supporting device 30a is able to support and maintain the side board 20 which has a greater height in the D3 direction in a vertical state. Furthermore, since the side board 20 may have electronic components disposed thereon, the weight distribution of the side board 20 may be uneven, resulting in an elevated center of gravity and/or a laterally shifted center of gravity. For example, when a relatively larger and/or heavier electronic component is disposed on one side of the side board 20 and/or disposed at a higher position in the normal direction of the main board 10, e.g., a heat dissipation device which is a relatively larger and heavier device is often disposed on the side board 20, the center of gravity of the side board 20 may be shifted toward one side and/or be elevated. Under this situation, increasing the extension length of the second plate 32 is helpful in maintaining the side board 20 in the vertical state. Similarly, when there is enough space on the side board 20, the first plate 31 can also be extended upwardly along the D3 direction for increasing contact and providing enhanced support with the side board 20.

The intersecting position between the first plate 31 and the second plate 32 can also be different. In an embodiment, as shown in FIG. 2A and FIG. 2B, the second plate 32 is intersecting with the first plate 31 at an edge thereof. In another embodiment, as shown in FIG. 2C, the second plate 32 is disposed on the surface of the first plate 31, and not intersecting with the first plate 31 at the edge thereof. Therefore, the intersection therebetween can be varied in accordance with the practical application without limitation.

In addition, at two opposite ends of the intersecting line between the first plate 31 and the second plate 32, the first plate 31 and the second plate 32 are coplanar at one end, and the first plate 31 protrudes from the second plate 32 at the other end. More specifically, the first plate 31 has a first edge 311 and a second edge 312 opposite to each other, the second plate 32 has a third edge 321 and a fourth edge 322 opposite to each other, the first edge 311 and the third edge 321 are coplanar, and a distance H1 between the first edge 311 and the second edge 312 is larger than a distance H2 between the third edge 321 and the fourth edge 322. That is, the first plate 31 and the second plate 32 have a structural step therebetween, and the first plate 31 protrudes out at one side of the second plate 32.

Through the structure design above, the auxiliary supporting device 30 of the present disclosure provides the advantage of universality. Even if there are different combinations between the side board 20 and the main board 10, a single structure can adapt thereto and maintain the side board 20 in a vertical state, which effectively solves the problem in the prior art of needing to customize different tools for different combinations between the side board 20 and the main board 10.

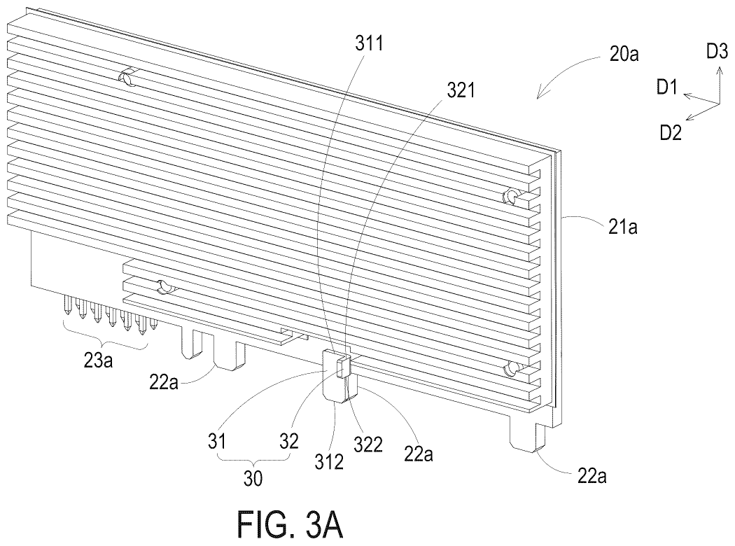

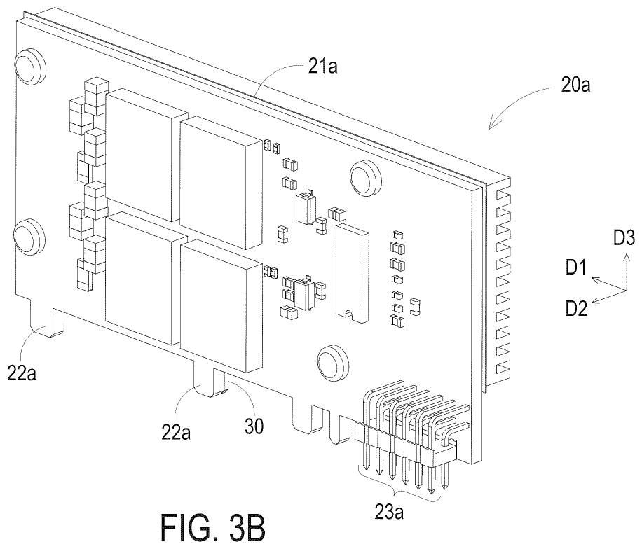

Following, different applications of the auxiliary supporting device 30 in the present disclosure are described accompanying with FIG. 3A to FIG. 5. For ease of understanding and clear representation, the main board is omitted and only the side board 20 and the auxiliary supporting device 30 are shown. One skilled in the art should understand that the side board 20 is vertically disposed on the main board in the practical application.

Please refer to FIG. 3A and FIG. 3B which illustrate a first application of an auxiliary supporting device according to an embodiment of the present disclosure. In this application, a side board 20a includes a main body 21a, a plurality of pins and a pin header connector 23a. In an embodiment, the main body 21a and the plurality of pins are integrally formed. The side board 20a is vertically disposed on the main board, the main board includes slots (not shown) for receiving the plurality of pins, and the pin header connector 23a is also disposed on the main board. The auxiliary supporting device 30 is disposed on a pin 22a of the plurality of pins and at one of two opposite sides in a D2 direction of the pin 22a. The first edge 311 of the first plate 31 is higher than the second edge 312 in the D3 direction, and the fourth edge 322 (bottom edge) of the second plate 32 is aligned with the bottom edge of the main body 21a, so that a portion of the first plate 31 is attached to the main body 21a at the upper position, and another portion thereof is attached to the pin 22a at the lower position. That is, the orientation of the auxiliary supporting device 30 is that the fourth edge 322 of the second plate 32 is higher than the second edge 312 of the first plate 31 in the D3 direction. Accordingly, the portion of the first plate 31 protruding from the second plate 32 is downward and inserts in the slot on the main board together with the pin 22a, and the second plate 32 together with the main body 21a of the side board 20a are disposed on a surface of the main board facing the side board 20a, in other words, the bottom edge of the second plate 32 is aligned with the bottom edge of the main body 21a.

In this application, since the pin header connector 23a is disposed at the bottom edge of the main body 21a and at one end thereof in a D1 direction, the side board 20a can be maintained in a vertical state by disposing the auxiliary supporting device 30 at the pin 22a at the other end of the main body 21a to cooperate with the pin header connector 23a. Therefore, there is no limitation on the position of the auxiliary supporting device 30, as long as it is disposed at a pin where can maintain balance with the pin header connector 23a. In addition, the auxiliary supporting device 30 and the pin header connector 23a are positioned at the opposite sides in the D2 direction of the side board 20a so as to further prevent the side board 20a from tilting or tipping. Alternatively, in accordance with the amount and position of the pin header connector, it also can be implemented to have more than one auxiliary supporting device 30, for example, auxiliary supporting devices 30 can be disposed at multiple pins 22a and/or disposed at opposite sides in the D2 direction of the side board 20, which can be varied in accordance with the practical situation.

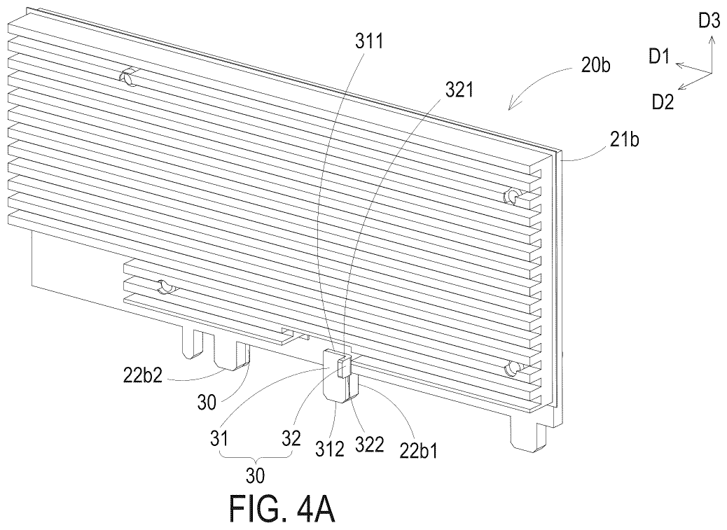

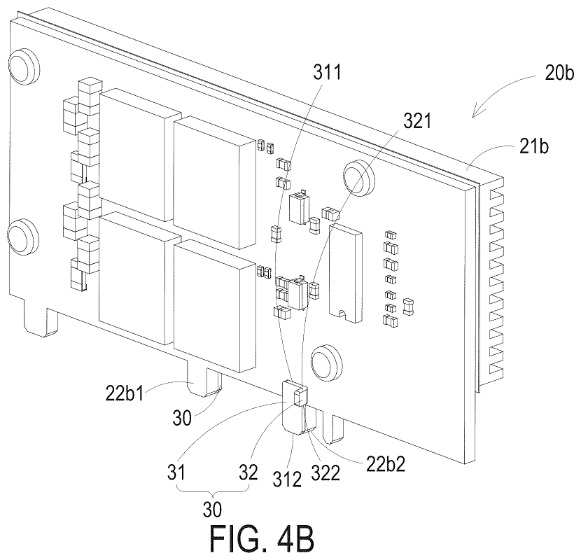

Please refer to FIG. 4A and FIG. 4B which illustrate a second application of an auxiliary supporting device according to an embodiment of the present disclosure. In this application, an side board 20b includes a main body 21b and a plurality of pins. In an embodiment, the main body 21b and the plurality of pins are integrally formed. The side board 20b is vertically disposed on the main board, and the main board includes slots (not shown) for receiving the plurality of pins. The auxiliary supporting devices 30 are disposed at two opposite sides in the D2 direction of the side board 20b, such as at opposite sides of pin 22b1 and pin 22b2. For each auxiliary supporting device 30, the first edge 311 of the first plate 31 is higher than the second edge 312 in the D3 direction, and the fourth edge 322 (bottom edge) of the second plate 32 is aligned with the bottom edge of the main body 21b, so that a portion of the first plate 31 is attached to the main body 21b at the upper position, and another portion thereof is attached to the pin 22b1, 22b2 at the lower position. That is, the orientation of each auxiliary supporting device 30 is that the fourth edge 322 of the second plate 32 is higher than the second edge 312 of the first plate 31 in the D3 direction. Accordingly, the portion of the first plate 31 protruding from the second plate 32 is downward and inserts in the slot on the main board together with the pin 22b1, 22b2, and the second plate 32 together with the main body 21b of the side board 20b are disposed on a surface of the main board facing the side board 20b, in other words, the bottom edge of the second plate 32 is aligned with the bottom edge of the main body 21b.

In this application, since there are only pins located at the bottom edge of the side board 20b, it is necessary to dispose the auxiliary supporting devices 30 respectively at opposite sides in the D2 direction of the side board 20b for preventing from tilting and tipping. In other embodiments, the auxiliary supporting devices 30 are respectively disposed at opposite sides in the D2 direction of different pins, that is, projections of the auxiliary supporting devices 30, which are at opposite sides, on the plane of the side board 20b are at least partially mismatched or not completely overlapped, which facilitates to more stably maintain the vertical state of the side board 20b. When a length of the side board 20b in the D1 direction is greater, increasing the separation distance between auxiliary supporting devices 30 can be more helpful in maintaining a stable vertical state of the side board 20b. Alternatively, the stabilization of side board can also be achieved by further increasing the amount of auxiliary supporting devices 30, for example, by disposing auxiliary supporting devices 30, at intervals, at opposite sides in the D2 direction of the side board 20b. Therefore, the amount and positions of auxiliary supporting devices 30 can be varied in accordance with the practical situation.

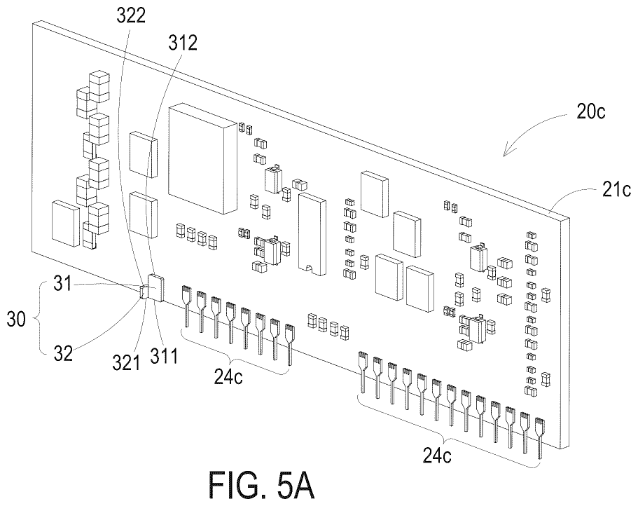

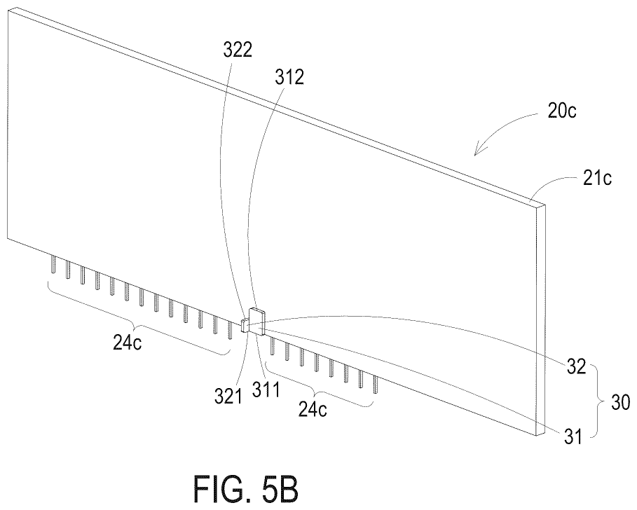

Please refer to FIG. 5A and FIG. 5B which illustrate a third application of an auxiliary supporting device according to an embodiment of the present disclosure. In this application, an side board 20c includes a main body 21c and connection terminals 24c. Different from side boards shown in FIG. 3A to FIG. 4B, the side board 20c does not have pins inserted in the main board, so that the auxiliary supporting device 30 is disposed on the surface of the main board facing the side board 20c via the first edge 311 of the first plate 31 and the third edge 321 of the second plate 32 which are coplanar, thereby responding to the situation that the side board 20c and the main board do not have pin and slot respectively. Accordingly, the orientation of auxiliary supporting device 30 is that the fourth edge 322 of the second plate 32 is lower than the second edge 312 of the first plate 31 in the D3 direction. In other words, compared with two previous applications, the auxiliary supporting device 30 shown in FIG. 5A and FIG. 5B is rotated 180 degrees, and the portion of the first plate 31 protruding from the second plate 32 turns upward. Under this situation, the first edge 311 of the first plate 31 and the third edge 321 of the second plate 32 ae aligned with the bottom edge of the main body 21c, the first plate 31 is attached to the main body 21c to maintain the side board 20c in a vertical state, and the second plate 32 is extended away from the first plate 31 for supporting.

In this application, the auxiliary supporting devices 30 have to be disposed at opposite sides in the D2 direction of the side board 20c, so as to avoid tilting or tipping, and the positions of the auxiliary supporting devices 30 can be varied in accordance with the distributions of electronic components respectively on the side board 20c and the main board, and also, the length of the side board 20c in the D1 direction. In other embodiments, auxiliary supporting devices 30 disposed at opposite sides in the D2 direction are not aligned with each other, in other words, projections of the auxiliary supporting devices 30 at opposite sides on the plane of the side board 20c are at least partially mismatched or not completely overlapped, so as to more stably maintain the side board 20c in a vertical state. Similarly, the amount and positions of auxiliary supporting devices 30 can be varied in accordance with the practical situation.

In summary, it can be known that no matter what kind of orientation the auxiliary supporting device 30 of the present disclosure is adopted, the bottom edge of the second plate 32 is always placed against the surface of the main board facing the side board, for example, in the applications shown in FIG. 3A to FIG. 4B, the bottom edge of the second plate 32 placed against the main board is the fourth edge 322, and in the application shown in FIG. 5A to FIG. 5B, the bottom edge of the second plate 32 placed against the main board is the third edge 321. On the other hand, the portion of the first plate 31 protruding from the second plate 32 is selectively to be downward to insert in the slot on the main board together with the pin, or to be upward when the side board does not have pins mounted thereon.

Consequently, by simply changing the orientation, the auxiliary supporting device 30 of the present disclosure can universally adapt to various side boards 20, 20a, 20b, 20c, such as with or without pins or pin header connector, for maintaining thereof in the vertical state. One single structure can advantageously meet all kinds of requirements for maintaining the side board in a vertical state.

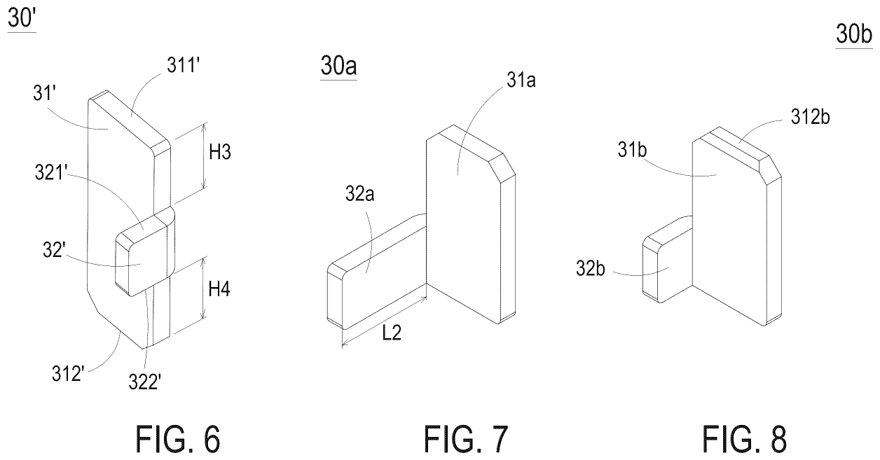

In another aspect of the present disclosure, the first plate and the second plate can have different relative relationships. Please refer to FIG. 6 which is a schematic view showing an auxiliary supporting device according to another embodiment of the present disclosure. An auxiliary supporting device 30′ includes a first plate 31′ and a second plate 32′. The first plate 31′ is parallel to the side board 20, and the second plate 32′ is extended from the first plate 31′ in a direction away from the side board 20. In this embodiment, the first plate 31′ has a first edge 311′ and a second edge 312′ opposite to each other, and the second plate 32′ has a third edge 321′ and a fourth edge 322′ opposite to each other, wherein the first edge 311′ and the third edge 321′ have a distance H3 therebetween, the fourth edge 322′ and the second edge 312′ have a distance H4 therebetween, and H3 an H4 are both greater than zero. That is, the first plate 31′ respectively protrudes from opposite sides of the second plate 32′, and structural steps are formed at opposite sides of the second plate 32′ by the first plate 31′. Under this situation, the auxiliary supporting device 30′ is suitable for the applications shown in FIG. 3A to FIG. 4B, the situation that the main board has slot(s) disposed thereon. Alternatively, in other embodiments, the second plate 32′ also can be implemented to dispose on the surface of the first plate 31′, similar to the embodiment shown in FIG. 2C, and not intersecting with the first plate 31′ at the edge thereof, which identically can achieve the supporting. Therefore, the intersection between the first plate and the second plate can be varied in accordance with the practical application without limitation.

The auxiliary supporting device 30, 30′ of the present disclosure and the side board are fixed through soldering. In the applications shown in FIG. 3A to FIG. 4B, the first plate 31, 31′ is simultaneously soldered to the main body of the side board and the pin, and in the application shown in FIG. 5A to FIG. 5B, the first plate 31, 31′ is soldered to the main body of the side board. Accordingly, the auxiliary supporting device 30, 30′ of the present disclosure can be made of metal material or formed by tin plating on the surface thereof, for example, by tin plating on the surface of SPCC (Steel Plate Cold Commercial). Pad(s) is disposed on the side board at a position corresponding to the first plate 31, 31′. Since the function of the auxiliary supporting device 30, 30′ is to support the side board and does not involve in signal transmission, there is no limitation on the material thereof, as long as it can be fixed through soldering.

The advantage of achieving the fixing by soldering is that it only needs to add the pad(s) at the corresponding position on the side board, and the original soldering process for soldering the electronic components can be directly used to complete the fixing of the auxiliary supporting device 30, 30′, which is very cost-effective. In practice, the auxiliary supporting device 30, 30′ which is disposed on the side board 20 is soldered and fixed simultaneously during the reflow soldering process of the side board 20. Then, the side board 20 with the auxiliary supporting device 30, 30′ is disposed on the main board in a vertical state. If it is the situation that the side board and the main board are performing the wave soldering process together, as the applications shown in FIG. 3A to FIG. 4B where a portion of the first plate 31, 31′ is inserted in the slot on the main board together with the pin, then the inserted portion of the first plate 31, 31′ is melted during the wave soldering process, and other portion thereof remains unmelted so as to keep supporting the side board in the vertical state. On the other hand, if it is the situation that the side board does not participate in the wave soldering process of the main board, as the application shown in FIG. 5A to FIG. 5B, then the auxiliary supporting device 30 will not be melted and will keep supporting the side board in the vertical state.

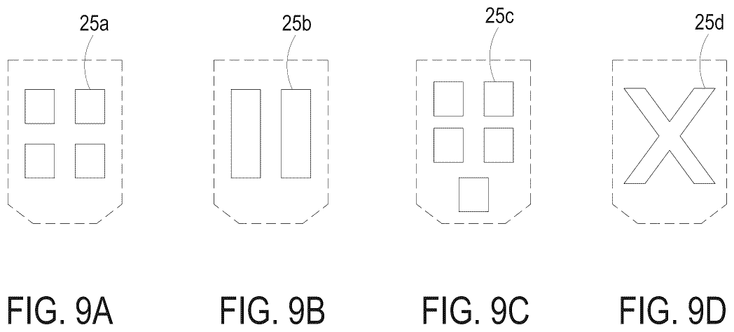

The pad(s) disposed on the side board 20 is defined by the shape and position of the first plate 31, 31′. For example, it can be single pad corresponding to the plate 31, 31′ of one single auxiliary supporting device 30, 30′, or it also can be multiple pads corresponding to the plate 31, 31′ of one single auxiliary supporting device 30, 30′. In some embodiments, in order to prevent the auxiliary supporting device 30, 30′ from floating during the soldering process, the area of the pad(s) is smaller than the contact area between the first plate 31, 31′ and the side board 20, so as to leave the overflow space within the soldering range; and when it is implemented to have multiple pads, each pad can be independently separated or at least partially staggered, that is, the multiple pads are not completely overlapped, so as to optimize the fixation of the auxiliary supporting device 30, 30′. For example, as shown in FIG. 9A, pads 25a are located at four corners of the area corresponding to the first plate on the side board 20; or as shown in FIG. 9B, pads 25b are two parallel regions in the area corresponding to the first plate on the side board 20; or as shown in FIG. 9C, pads 25c are multiple points in the area corresponding to the first plate on the side board 20; or as shown in FIG. 9D, pad 25d has a different configuration. The key is to evenly distribute the solder to avoid the auxiliary supporting device from floating.

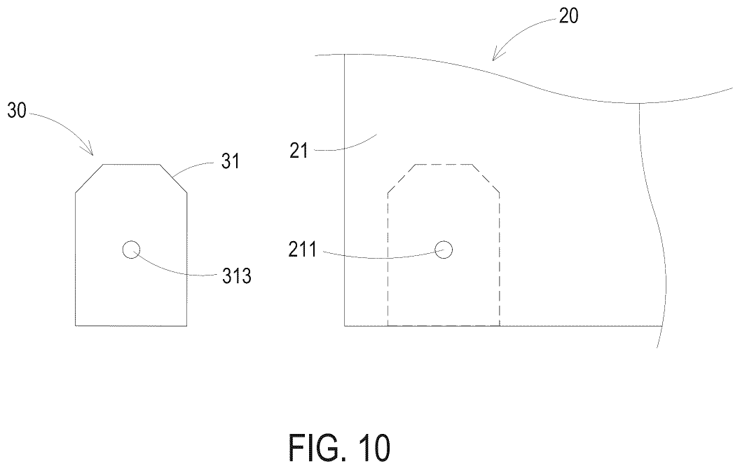

Other than adopting the soldering process for fixing, the positioning between the auxiliary supporting device and the side board can further be achieved by disposing engaging portions. In an embodiment, as shown in FIG. 10, on the surface of the first plate 31 of the auxiliary supporting device 30 for contacting the side board 20, a first engaging portion 313 can be disposed, and a second engaging portion 211 corresponding to the first engaging portion 313 can be disposed on the main body 21 of the side board 20, so that through the engagement therebetween, the positioning between the auxiliary supporting device and the side board can be further ensured. For example, the first engaging portion can be a protruded structure, such as a positioning protrusion, and the second engaging portion can be a recess structure, such as a positioning hole, or oppositely, the first engaging portion can be a recess structure and the second engaging portion can be a protruded structure, which can be varied in accordance with the practical situation without limitation.

When a portion of the first plate is inserted in the slot on the main board together with the pin, there is no limitation on the shape of the first plate. The shape of the first plate can be identical to or different from the shape of the pin, and/or the second edge of the first plate can be aligned or not aligned with the bottom edge of the pin. In some embodiments, the second edge of the first plate body is shaped to substantially match the contour of the pin. This configuration helps to prevent any step difference between the second edge of the first plate body and an edge of the pin, thereby avoiding solder wicking during the wave soldering process and ensuring improved soldering quality. In addition, the second edge of the first plate can be further chamfered for improving the soldering quality. For example, as shown in FIG. 2B, two ends of the second edge 312 of the first plate 31 are chamfered, or as shown in FIG. 8, an auxiliary supporting device 30b includes a first plate 31b and a second plate 32b, wherein two ends of a second edge 312b of the first plate 31b are chamfered and one side of the second edge 312b parallel to and away from the side board is also chamfered, so as to optimize the soldering quality. Therefore, the shape of the first plate, especially the portion that is inserted in the slot on the main board with the pin, can be varied in accordance with the shape of the pin without limitation.

In conclusion, the present disclosure provides the auxiliary supporting device with innovative structural design which is capable of adapting to different combinations between the main board and the side board in the power module, thereby universally maintaining various kinds of side boards in the vertical state. Moreover, the auxiliary supporting device is fixed to the side board through soldering, which can be achieved at the same with the original soldering process for the power module and is easy to conduct. In addition, the auxiliary supporting device of the present disclosure is also cost effective due to the simple structure and unlimited material thereof.

It is to be understood that the disclosure is not limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An auxiliary supporting device for maintaining a first circuit board in a vertical state on a second circuit board, comprising:
a first plate parallel to and fixed to the first circuit board; and
a second plate extended from the first plate in a direction away from the first circuit board, wherein a bottom edge of the second plate is disposed on a surface of the second circuit board facing the first circuit board.

2. The auxiliary supporting device as claimed in claim 1, wherein an intersecting angle between a plane of the second plate and a plane of the first plate is ranged between 45°and 135°.

3. The auxiliary supporting device as claimed in claim 2, wherein the intersecting angle between the planes of the second plate and the plane of the first plate is 90°.

4. The auxiliary supporting device as claimed in claim 1, wherein an extension length of the second plate from the first plate is positively related to a height of the first circuit board in a normal direction of the second circuit board.

5. The auxiliary supporting device as claimed in claim 1, wherein the first plate is inserted in a slot of the second circuit board at least in part.

6. The auxiliary supporting device as claimed in claim 5, wherein a portion of the first plate is attached to a main body of the first circuit board, another portion of the first plate is attached to a pin of the first circuit board, and the another portion of the first plate is inserted in the slot with the pin.

7. The auxiliary supporting device as claimed in claim 6, wherein a bottom edge of the first plate is aligned with a bottom edge of the pin.

8. The auxiliary supporting device as claimed in claim 6, wherein the pin and the main body are integrally formed.

9. The auxiliary supporting device as claimed in claim 1, wherein a bottom edge of the first plate is chamfered.

10. The auxiliary supporting device as claimed in claim 1, wherein a bottom edge of the first plate and the bottom edge of the second plate are coplanar and placed against the surface of the second circuit board facing the first circuit board.

11. The auxiliary supporting device as claimed in claim 1, wherein the first plate further comprises a first engaging portion, the first circuit board further comprises a second engaging portion, and the first engaging portion and the second engaging portion are engaged with each other for positioning the auxiliary supporting device.

12. The auxiliary supporting device as claimed in claim 11, wherein the first engaging portion is a positioning protrusion, and the second engaging portion is a positioning hole.

13. The auxiliary supporting device as claimed in claim 1, wherein the first plate and the second plate are integrally formed.

14. A power module comprising at least one auxiliary supporting device as claimed in claim 1, a first circuit board and a second circuit board, wherein the at least one auxiliary supporting device is configured to maintain the first circuit board in a vertical state on the second circuit board.

15. The power module as claimed in claim 14, wherein at least one pad is disposed on the first circuit board at a position corresponding to the first plate, so as to attach the first plate to the first circuit board through soldering.

16. The power module as claimed in claim 15, wherein the at least one pad comprises a plurality of pads disposed on the first circuit board, and the plurality of pads are at least partially non-overlapping.

17. The power module as claimed in claim 14, wherein the at least one auxiliary supporting device comprises a plurality of auxiliary supporting devices respectively disposed at two opposite sides of the first circuit board.

18. The power module as claimed in claim 17, wherein projections of the plurality of auxiliary supporting devices on a plane of the first circuit board are at least partially non-overlapping.

19. The power module as claimed in claim 14, wherein the at least one auxiliary supporting device is disposed at one end of the first circuit board and a pin header connector is disposed at the other end of the first circuit board.

20. The power module as claimed in claim 14, wherein the first circuit board has a heat dissipation device disposed thereon.
